(19) United States
(12) Patent Application Publication
(10) Pub. No.: US 2020/0243657 A1
(43) Pub. Date: Jul. 30, 2020

(54) Multi-trench MOSFET and method for fabricating the same

(71) Applicant: He Ding Technology Co., Ltd., New Taipei City (TW)

(72) Inventor: Yuan-Shun CHANG, New Taipei City (TW)

(21) Appl. No.: 16/424,533

(22) Filed: May 29, 2019

(30) Foreign Application Priority Data
Jan. 30, 2019 (TW) 108103592

(51) Int. Cl. H01L 29/423; H01L 29/66; H01L 29/78; H01L 21/8234

(52) U.S. Cl. CPC H01L 29/4236; H01L 21/823437; H01L 29/7813; H01L 29/66734

(57) ABSTRACT

A multi-trench MOSFET includes a drain region, a body region, first trenches, first gates, second trenches, second gates, and source regions. The body region is disposed on the drain region. The first trenches are disposed side by side and extend in a first direction. The first trenches pass through the body region to enter into the drain region. The first gates are disposed in the first trenches respectively. The second trenches are disposed side by side and extend in a second direction different from the first direction. The second trenches pass through the body region to enter into the drain region. The first trenches and the second trenches are connected to divide the body region into blocks. A width of the second trench is 1.5 to 4 times that of the first trench. The second gates are disposed in the second trenches respectively. The source regions are disposed in the body region and abut the first trenches and the second trenches.

### TECHNICAL FIELD

The invention relates to a metal-oxide-semiconductor field-effect transistor (MOSFET) and a method for fabricating the same and, more particularly, to a trench MOSFET and a method for fabricating the same.

### RELATED ART

Metal-oxide-semiconductor field-effect transistors (MOSFETs) are widely applied to switching components of power devices, such as power supplies, rectifiers, and low-voltage motor controllers. Conventional power MOSFETs are mostly designed with vertical structures, such as trench MOSFETs, to increase the density of components. Conventional trench MOSFETs can be classified into strip-cell and closed-cell designs. However, in the strip-cell or closed-cell design, gates disposed in trenches use a single gate structure.

### SUMMARY

An objective of the invention is to provide a multi-trench MOSFET and a method for fabricating the same, using the closed-cell design, in which gates disposed in trenches of different directions use different gate structures. By a clever arrangement of process steps, only one mask needs to be added, so that the density of channels can be significantly increased to reduce on-resistance, and the cost can be reduced.

To achieve the above objective, the invention provides a multi-trench MOSFET including a drain region, a body region, first trenches, first gates, second trenches, second gates, and source regions. The drain region has a first conductivity type. The body region has a second conductivity type opposite to the first conductivity type. The body region is disposed on the drain region. The first trenches are disposed side by side and extend in a first direction. The first trenches pass through the body region to enter into the drain region. The first gates are disposed in the first trenches respectively. The second trenches are disposed side by side and extend in a second direction different from the first direction. The second trenches pass through the body region to enter into the drain region. The first trenches and the second trenches are connected to divide the body region into blocks. A width of the second trench is 1.5 to 4 times that of the first trench. The second gates are disposed in the second trenches respectively. The source regions have the first conductivity type. The source regions are disposed in the body region and abut the first trenches and the second trenches.

In an embodiment of the invention, the first gate uses a first gate structure or a second gate structure. The first gate structure includes a first oxide layer and a first gate electrode. The first oxide layer is disposed on a bottom wall and two side walls of the first trench. The first gate electrode is disposed on the first oxide layer and fills the first trench. The second gate structure includes a second oxide layer, a third oxide layer, and a second gate electrode. The second oxide layer is disposed on the bottom wall of the first trench. A thickness of the second oxide layer is greater than that of the first oxide layer. The third oxide layer is disposed on the two side walls of the first trench and the second oxide layer. The second gate electrode is disposed on the third oxide layer and fills the first trench.

In an embodiment of the invention, if a depth of the second trench is the same as that of the first trench, the second gate uses a third gate structure. The third gate structure includes a fourth oxide layer and a third gate electrode. The fourth oxide layer is disposed on a bottom wall and two side walls of the second trench. The third gate electrode is disposed on the fourth oxide layer and fills the second trench.

In an embodiment of the invention, if the depth of the second trench is greater than that of the first trench, the second gate uses a fourth gate structure, a fifth gate structure, or a sixth gate structure. The fourth gate structure includes a fifth oxide layer and a fourth gate electrode. The fifth oxide layer is disposed on the bottom wall and the two side walls of the second trench. The fourth gate electrode is disposed on the fifth oxide layer and fills the second trench. The fifth gate structure includes a sixth oxide layer, a first shield electrode, a seventh oxide layer, and a fifth gate electrode. The sixth oxide layer is disposed on the bottom wall of the second trench. The first shield electrode is disposed on the sixth oxide layer. The seventh oxide layer is disposed on the two side walls of the second trench, the sixth oxide layer, and the first shield electrode. The seventh oxide layer and the sixth oxide layer surround the first shield electrode. The fifth gate electrode is disposed on the seventh oxide layer and fills the second trench. The sixth gate structure includes an eighth oxide layer, a second shield electrode, a ninth oxide layer, a tenth oxide layer, a sixth gate electrode, and a seventh gate electrode. The eighth oxide layer is disposed on the bottom wall of the second trench. The second shield electrode is disposed on the eighth oxide layer. The ninth oxide layer is disposed on the eighth oxide layer, one of the two side walls of the second trench, and a side surface of the second shield electrode. The tenth oxide layer is disposed on the eighth oxide layer, the other one of the two side walls of the second trench, and another side surface of the second shield electrode. The sixth gate electrode is disposed on the ninth oxide layer. The seventh gate electrode is disposed on the tenth oxide layer. The sixth gate electrode and the seventh gate electrode fill the second trench.

In an embodiment of the invention, the drain region includes a substrate and an epitaxial layer. The substrate has the first conductivity type. The epitaxial layer has the first conductivity type. The epitaxial layer is disposed on the substrate. The body region is disposed on the epitaxial layer.

The invention further provides a method for fabricating the above-mentioned multi-trench MOSFET including: providing the drain region; forming the first trenches and the second trenches on the drain region, forming the first gates and the second gates in the first trenches and the second trenches respectively; forming the body region in a top portion of the drain region; and forming the source regions in the body region.

In an embodiment of the invention, if the depth of the second trench is greater than that of the first trench, forming the first trenches and the second trenches includes: forming a hard mask on the drain region, and forming a first patterned photoresist on the hard mask, the first patterned photoresist exposing portions of the hard mask corresponding to the second trenches; etching the portions of the hard mask exposed through the first patterned photoresist to form a first patterned hard mask, and then removing the first patterned photoresist; etching a portion of the drain region exposed through the first patterned hard mask to form auxiliary trenches; forming a second patterned photoresist on the first patterned hard mask, the second patterned photoresist exposing portions of the first patterned hard mask corresponding to the first trenches and the second trenches; etching the portions of the first patterned hard mask exposed through the second patterned photoresist to form a second patterned hard mask, and then removing the second patterned photoresist, wherein the second patterned hard mask exposing portions of the drain region corresponding to the first trenches and the auxiliary trenches; and etching the portions of the drain region exposed through the second patterned hard mask to form the first trenches and the second trenches, wherein the second trench is obtained by further etching the auxiliary trench.

In an embodiment of the invention, if the first gate uses the second gate structure, forming the first gates and the second gates in the first trenches and the second trenches respectively includes: forming a first auxiliary oxide layer on the drain region by using a thin-film deposition technique, the first auxiliary oxide layer filling the first trenches and the second trenches; forming a patterned photoresist on the first auxiliary oxide layer, the patterned photoresist exposing portions of the first auxiliary oxide layer corresponding to the second trenches; etching the portions of the first auxiliary oxide layer exposed through the patterned photoresist, so that a second auxiliary oxide layer being left in each second trench; and removing the patterned photoresist, and etching the remaining first auxiliary oxide layer and the remaining second auxiliary oxide layer, so that the second auxiliary oxide layer left in each second trench disappears, and the first auxiliary oxide layer is etched to leave an oxide layer disposed on the bottom wall of each first trench to serve as the second oxide layer of the second gate structure.

In an embodiment of the invention, providing the drain region includes: providing a substrate having the first conductivity type; and forming an epitaxial layer having the first conductivity type on the substrate. The substrate and the epitaxial layer constitute the drain region. The first trenches and the second trenches are formed on the epitaxial layer. The body region is formed in a top portion of the epitaxial layer.

The above and other objectives, features, and advantages of the invention will be better understood from the following detailed description of the preferred embodiments of the invention that are illustrated in the accompanying drawings.

### BRIEF DESCRIPTION OF THE DRAWINGS

FIG. 1 is a schematic top view of a multi-trench MOSFET according to an embodiment of the invention:

FIG. 2A is a schematic cross-sectional view of the multi-trench MOSFET including a first trench using a first gate structure according to an embodiment of the invention:

FIG. 2B is a schematic cross-sectional view of the multi-trench MOSFET including a first trench using a second gate structure according to an embodiment of the invention;

FIG. 3A is a schematic cross-sectional view of the multi-trench MOSFET including a second trench using a third gate structure according to an embodiment of the invention;

FIG. 3B is a schematic cross-sectional view of the multi-trench MOSFET including a second trench using a fourth gate structure according to an embodiment of the invention;

FIG. 3C is a schematic cross-sectional view of the multi-trench MOSFET including a second trench using a fifth gate structure according to an embodiment of the invention;

FIG. 3D is a schematic cross-sectional view of the multi-trench MOSFET including a second trench using a sixth gate structure according to an embodiment of the invention;

FIG. 4A to FIG. 4F are schematic flow diagrams of a method for fabricating the multi-trench MOSFET according to a first embodiment of the invention;

FIG. 5A to FIG. 5F are schematic flow diagrams of a method for fabricating the multi-trench MOSFET according to a second embodiment of the invention;

FIG. 6A to FIG. 6F are schematic flow diagrams of a method for fabricating the multi-trench MOSFET according to a third embodiment of the invention:

FIG. 7A to FIG. 7F are schematic flow diagrams of a method for fabricating the multi-trench MOSFET according to a fourth embodiment of the invention; and

FIG. 8A to FIG. 8F are schematic flow diagrams of a method for fabricating the multi-trench MOSFET according to a fifth embodiment of the invention.

### DETAILED DESCRIPTION

For clarity, components in the accompanying drawings are only illustrative and not drawn according to shapes and scales of physical objects, and some of known components are omitted. In addition, for consistency, same or similar reference numerals are used in the drawings and the description to refer to the same or like components. Directional terms, such as up, down, left, right, front and back, may be used with respect to the drawings. These and similar directional terms should not be construed to limit the scope of the invention in any manner.

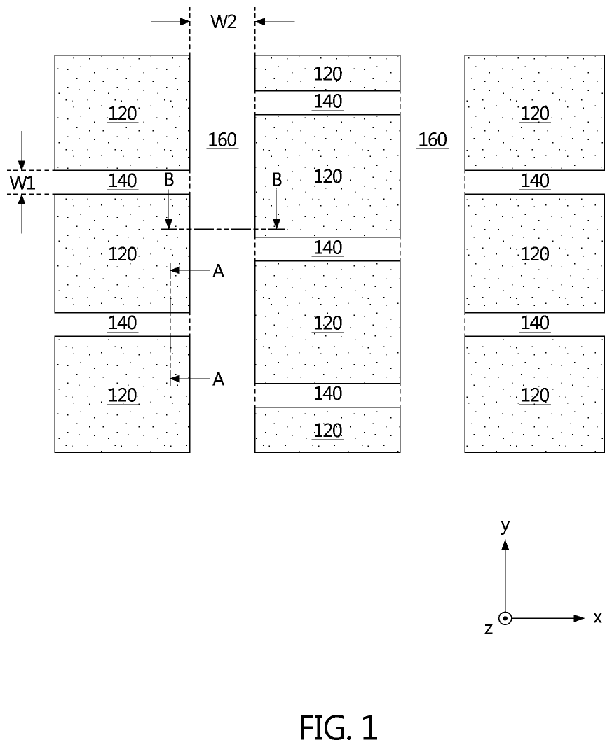

Please refer to FIG. 1. FIG. 1 is a schematic top view of a multi-trench MOSFET according to an embodiment of the invention. The multi-trench MOSFET includes a body region 120, first trenches 140, and second trenches 160. The first trenches 140 are disposed side by side and extend in a first direction x. The second trenches 160 are disposed side by side and extend in a second direction y different from the first direction x. In the embodiment, the first direction x and the second direction y are perpendicular to each other; moreover, a third direction z and the first direction x are perpendicular to each other, while the third direction z and second direction y are perpendicular to each other. The first trenches 140 and the second trenches 160 are connected to divide the body region 120 into blocks. A width W2 of the second trench 160 is 1.5 to 4 times a width W1 of the first trench 140. For example, if the width W1 of the first trench 140 is 0.2 micrometer (μm), the width W2 of the second trench 160 is 0.3 to 0.8 μm. The multi-trench MOSFET further includes a drain region, first gates, second gates, and source regions, none of which are shown in FIG. 1 and will be described in detail below.

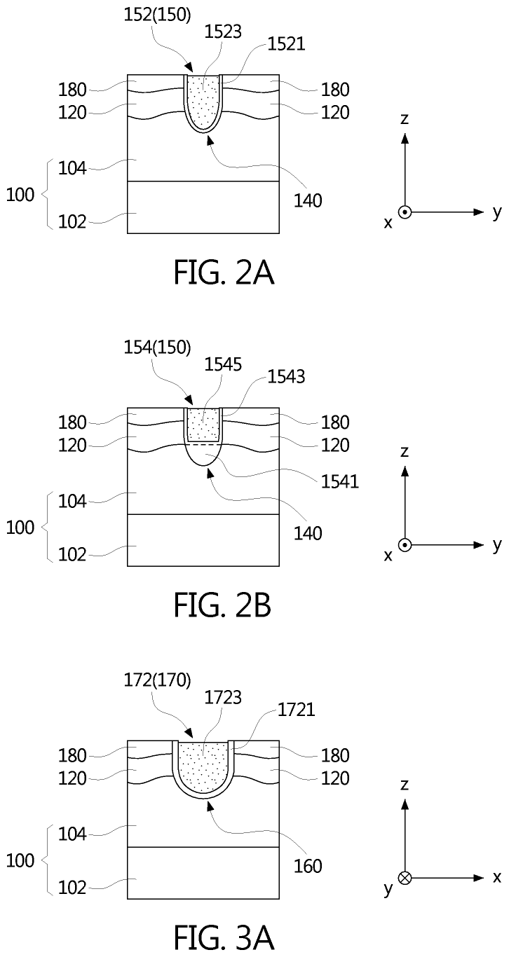

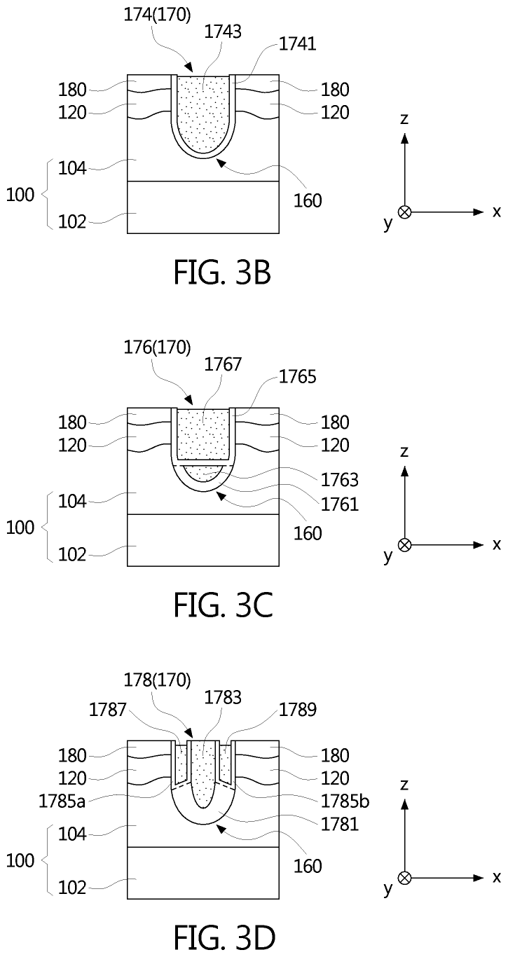

Please refer to FIG. 1, FIG. 2A, and FIG. 3A. FIG. 2A is a schematic cross-sectional view of the multi-trench MOSFET including the first trench 140 using a first gate structure 152 according to an embodiment of the invention. FIG. 3A is a schematic cross-sectional view of the multi-trench MOSFET including the second trench 160 using a third gate structure 172 according to an embodiment of the invention. FIG. 2A is the schematic cross-sectional view taken along a line A-A in FIG. 1, and FIG. 3A is the schematic cross-sectional view taken along a line B-B in FIG. 1. The multi-trench MOSFET includes the drain region 100, the body region 120, the first trenches 140, the first gates 150, the second trenches 160, the second gates 170, and the source regions 180.

The drain region 100 has a first conductivity type. In the embodiment, the drain region 100 includes a substrate 102 and an epitaxial layer 104 disposed on the substrate 102 (as shown in FIG. 2A and FIG. 3A). Each of the substrate 102 and the epitaxial layer 104 has the first conductivity type. The doping concentration of the substrate 102 is greater than that of the epitaxial layer 104. The body region 120 has a second conductivity type opposite to the first conductivity type. For example, the first conductivity type is an N-type, and the second conductivity type is a P-type. The body region 120 is disposed on the epitaxial layer 104; in other words, the body region 120 is disposed on the entire drain region 100.

The first trenches 140 are disposed side by side and extend in the first direction x (as shown in FIG. 1). The first trenches 140 extend from a top surface of the body region 120 in the opposite direction of the third direction z and pass through the body region 120 to enter into the epitaxial layer 104 of the drain region 100 (as shown in FIG. 2A). The first gates 150 are disposed in the first trenches 140 respectively. In the embodiment, the first gate 150 uses the first gate structure 152. The first gate structure 152 includes a first oxide layer 1521 and a first gate electrode 1523. The first oxide layer 1521 is disposed on a bottom wall and two side walls of the first trench 140. The first gate electrode 1523 is disposed on the first oxide layer 1521 and fills the first trench 140.

The second trenches 160 are disposed side by side and extend in the second direction y; moreover, the first trenches 140 and the second trenches 160 are connected to divide the body region 120 into the blocks (as shown in FIG. 1). The second trenches 160 extend from the top surface of the body region 120 in the opposite direction of the third direction z and pass through the body region 120 to enter into the epitaxial layer 104 of the drain region 100 (as shown in FIG. 3A). The second gates 170 are disposed in the second trenches 160 respectively. In the embodiment, a depth of the second trench 160 is the same as that of the first trench 140, and the second gate 170 uses the third gate structure 172. The third gate structure 172 includes a fourth oxide layer 1721 and a third gate electrode 1723. The fourth oxide layer 1721 is disposed on a bottom wall and two side walls of the second trench 160. The third gate electrode 1723 is disposed on the fourth oxide layer 1721 and fills the second trench 160.

The source regions 180 have the first conductivity type, for example the N-type. The source regions 180 are disposed in the body region 120 and abut the first trenches 140 and the second trenches 160 (as shown in FIG. 2A and FIG. 3A). Therefore, the source regions 180 are disposed in inner peripheries of the blocks of the body region 120 respectively.

Although the first gate 150 in the first trench 140 of the embodiment uses the first gate structure 152, and the second gate 170 in the second trench 160 of the embodiment uses the third gate structure 172, it is not intended to limit the invention and will be described in detail below.

Please refer to FIG. 2B. FIG. 2B is a schematic cross-sectional view of the multi-trench MOSFET including the first trench 140 using a second gate structure 154 according to an embodiment of the invention. The first trench 140 has the first gate 150 disposed therein. In the embodiment, the first gate 150 uses the second gate structure 154. The second gate structure 154 includes a second oxide layer 1541, a third oxide layer 1543, and a second gate electrode 1545. The second oxide layer 1541 is disposed on the bottom wall of the first trench 140. A thickness of the second oxide layer 1541 is greater than that of the first oxide layer 1521. The third oxide layer 1543 is disposed on the two side walls of the first trench 140 and the second oxide layer 1541. The second gate electrode 1545 is disposed on the third oxide layer 1543 and fills the first trench 140. It is noted that the thicker second oxide layer 1541 is used on the bottom wall of the first trench 140 to reduce the gate capacitance, thereby reducing the switching loss and increasing the switching speed of the transistors.

Please refer to FIG. 3B. FIG. 3B is a schematic cross-sectional view of the multi-trench MOSFET including the second trench 160 using a fourth gate structure 174 according to an embodiment of the invention. The second trench 160 has the second gate 170 disposed therein. In the embodiment, the depth of the second trench 160 is greater than that of the first trench 140, and the second gate 170 uses the fourth gate structure 174. The fourth gate structure 174 includes a fifth oxide layer 1741 and a fourth gate electrode 1743. The fifth oxide layer 1741 is disposed on the bottom wall and the two side walls of the second trench 160. The fourth gate electrode 1743 is disposed on the fifth oxide layer 1741 and fills second trench 160.

Please refer to FIG. 3C. FIG. 3C is a schematic cross-sectional view of the multi-trench MOSFET including the second trench 160 using a fifth gate structure 176 according to an embodiment of the invention. The second trench 160 has the second gate 170 disposed therein. In the embodiment, the depth of the second trench 160 is greater than that of the first trench 140, and the second gate 170 uses the fifth gate structure 176. The fifth gate structure 176 includes a sixth oxide layer 1761, a first shield electrode 1763, a seventh oxide layer 1765, and a fifth gate electrode 1767. The sixth oxide layer 1761 is disposed on the bottom wall of the second trench 160. The first shield electrode 1763 is disposed on the sixth oxide layer 1761. The seventh oxide layer 1765 is disposed on the two side walls of the second trench 160, the sixth oxide layer 1761, and the first shield electrode 1763. The seventh oxide layer 1765 and the sixth oxide layer 1761 surround the first shield electrode 1763. The fifth gate electrode 1767 is disposed on the seventh oxide layer 1765 and fills the second trench 160. It is noted that the first shield electrode 1763 is designed to be electrically connected to the source region to become the source electrode, so that the original gate-drain capacitance (Cgd) becomes the drain-source capacitance (Cds) to greatly reduce the Miller capacitance, thereby increasing the switching efficiency and speed of the transistors.

Please refer to FIG. 3D. FIG. 3D is a schematic cross-sectional view of the multi-trench MOSFET including the second trench 160 using a sixth gate structure 178 according to an embodiment of the invention. The second trench 160 has the second gate 170 disposed therein. In the embodiment, the depth of the second trench 160 is greater than that of the first trench 140, and the second gate 170 uses the sixth gate structure 178. The sixth gate structure 178 includes an eighth oxide layer 1781, a second shield electrode 1783, a ninth oxide layer 1785a, a tenth oxide layer 1785b, a sixth gate electrode 1787, and a seventh gate electrode 1789. The eighth oxide layer 1781 is disposed on the bottom wall of the second trench 160. The second shield electrode 1783 is disposed on the eighth oxide layer 1781. The ninth oxide layer 1785a is disposed on the eighth oxide layer 1781, one of the two side walls of the second trench 160, and a side surface of the second shield electrode 1783. The tenth oxide layer 1785b is disposed on the eighth oxide layer 1781, the other one of the two side walls of the second trench 160, and another side surface of the second shield electrode 1783. The sixth gate electrode 1787 is disposed on the ninth oxide layer 1785a. The seventh gate electrode 1789 is disposed on the tenth oxide layer 1785b. The sixth gate electrode 1787 and the seventh gate electrode 1789 fill the second trench 160. It is noted that the second shield electrode 1783 is designed to be electrically connected to the source region to become the source electrode, so that the original gate-drain capacitance (Cgd) becomes the drain-source capacitance (Cds) to greatly reduce the Miller capacitance, thereby increasing the switching efficiency and speed of the transistors.

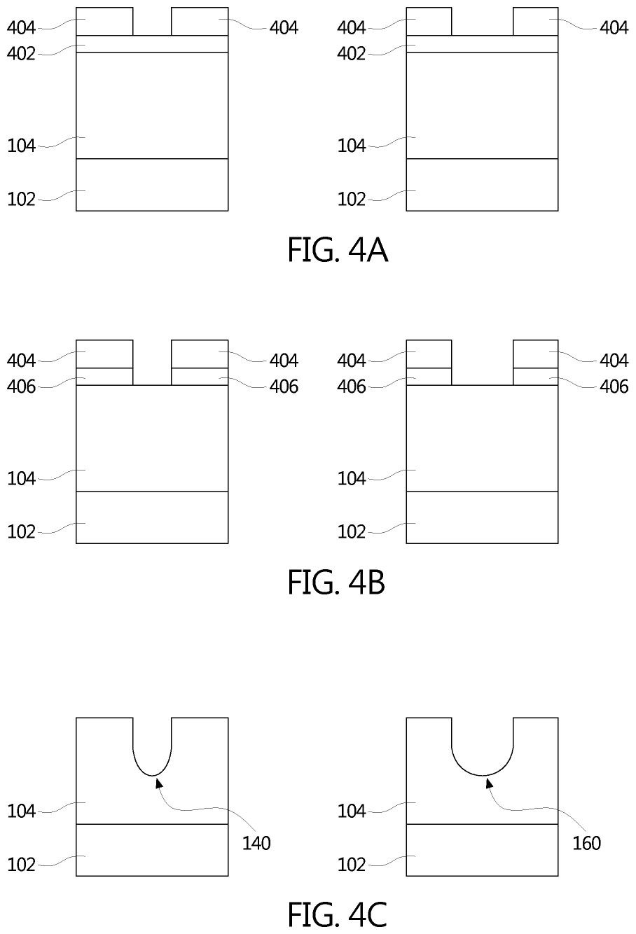

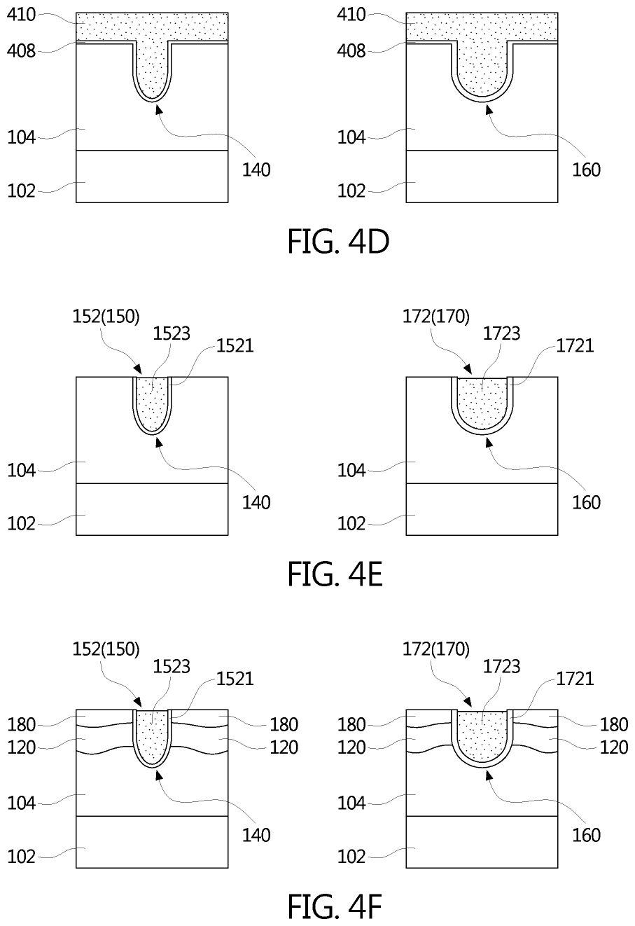

Please refer to FIG. 4A to FIG. 4F. FIG. 4A to FIG. 4F are schematic flow diagrams of a method for fabricating the multi-trench MOSFET according to a first embodiment of the invention, which only show the schematic cross-sectional view taken along the line A-A in FIG. 1 (the left image in each drawing) and the schematic cross-sectional view taken along the line B-B in FIG. 1 (the right image in each drawing). In the first embodiment, each first trench 140 uses the first gate structure 152, and each second trench 160 uses the third gate structure 172. As shown in FIG. 4A, the substrate 102 is provided, and the epitaxial layer 104 is formed on the substrate 102. The substrate 102 and the epitaxial layer 104 constitute the drain region 100. A hard mask 402 is formed on the epitaxial layer 104. A photoresist is formed on the hard mask 402, and then exposed and developed by using a mask to form a patterned photoresist 404. As shown in FIG. 4B, portions of the hard mask 402 exposed through the patterned photoresist 404 are etched to form a patterned hard mask 406. As shown in FIG. 4C, the patterned photoresist 404 is removed. Portions of the epitaxial layer 104 exposed through the patterned hard mask 406 are etched to form the first trenches 140 and the second trenches 160, and then the patterned hard mask 406 is removed. As shown in FIG. 4D, an oxide layer 408 is formed to cover the epitaxial layer 104, the first trenches 140, and the second trenches 160 by using a thermal oxidation manner. A polysilicon layer 410 is formed on the oxide layer 408 by using a thin-film deposition technique, such as chemical vapor deposition (CVD) and physical vapor deposition (PVD), and the polysilicon layer 410 fills the first trenches 140 and the second trenches 160.

As shown in FIG. 4E, the polysilicon layer 410 is back etched to remove a portion of the oxide layer 408 and a portion of the polysilicon layer 410 which go beyond the first trenches 140 and the second trenches 160. The remaining oxide layer 408 disposed on the bottom wall and the two side walls of each first trench 140 is the first oxide layer 1521 to serve as a gate oxide layer. The remaining polysilicon layer 410 disposed on the first oxide layer 1521 and filling each first trench 140 is the first gate electrode 1523. The first oxide layer 1521 and the first gate electrode 1523 constitute the first gate structure 152. The remaining oxide layer 408 disposed on the bottom wall and the two side walls of each second trench 160 is the fourth oxide layer 1721 to serve as a gate oxide layer. The remaining polysilicon layer 410 disposed on the fourth oxide layer 1721 and filling each second trench 160 is the third gate electrode 1723. The fourth oxide layer 1721 and the third gate electrode 1723 constitute the third gate structure 172. As shown in FIG. 4F, portions of the epitaxial layer 104 near a top surface thereof are transformed into the blocks of the body region 120 by an ion implantation manner, and then portions of the body region 120 near a top surface thereof are transformed into the source regions 180 by the ion implantation manner. Next, an oxide layer (not shown) is formed on the first gate structure 152 and the third gate structure 172, and then a metal layer (not shown) is formed on the oxide layer and the source regions 180 to serve as a source metal layer. Finally, a metal layer (not shown) is formed on a surface of the substrate 102 away from the epitaxial layer 104 to serve as a drain metal layer. The source and drain metal layers are not the features of the invention and can be achieved by conventional techniques, so they are not described in detail herein.

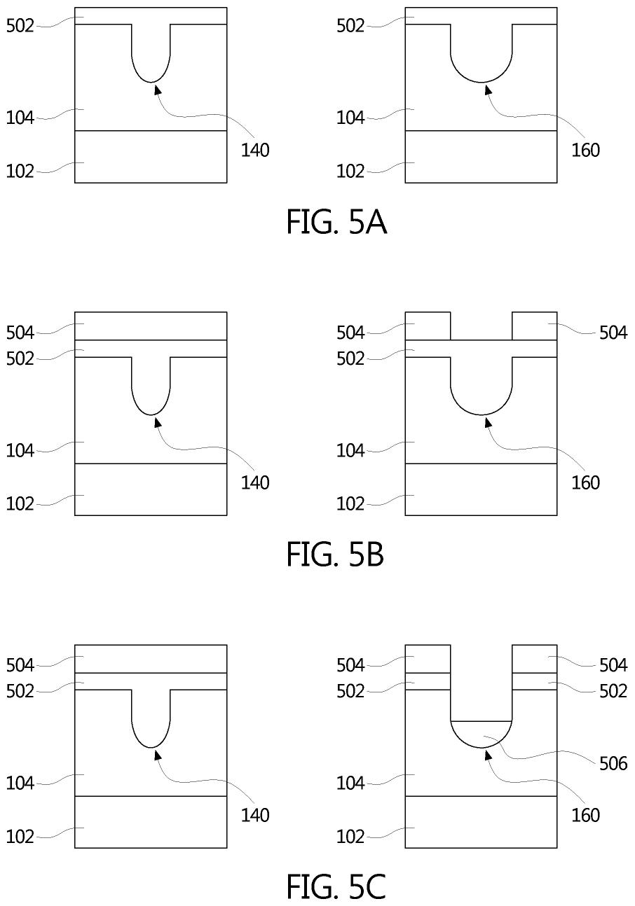

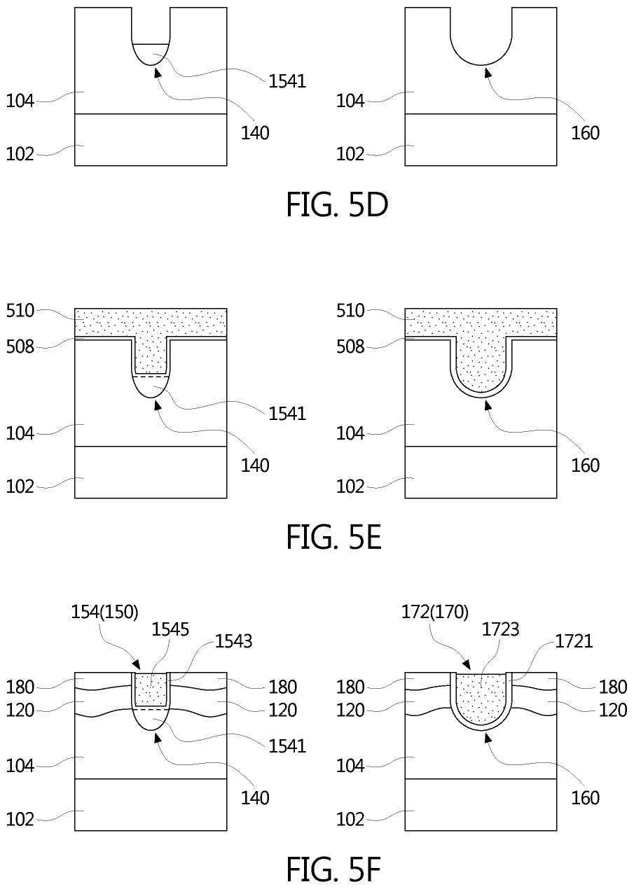

Please refer to FIG. 5A to FIG. 5F. FIG. 5A to FIG. 5F are schematic flow diagrams of a method for fabricating the multi-trench MOSFET according to a second embodiment of the invention, which only show the schematic cross-sectional view taken along the line A-A in FIG. 1 (the left image in each drawing) and the schematic cross-sectional view taken along the line B-B in FIG. 1 (the right image in each drawing). In the second embodiment, each first trench 140 uses the second gate structure 154, and each second trench 160 uses the third gate structure 172. As shown in FIG. 5A, by the steps shown in FIG. 4A to FIG. 4C, the first trenches 140 and the second trenches 160 are formed on the epitaxial layer 104. A first auxiliary oxide layer 502 is formed on the epitaxial layer 104 by using the thin-film deposition technique, and the first auxiliary oxide layer 502 fills the first trenches 140 and the second trenches 160. As shown in FIG. 5B, a patterned photoresist 504 is formed on the first auxiliary oxide layer 502. The patterned photoresist 504 exposes portions of the first auxiliary oxide layer 502 corresponding to the second trenches 160. As shown in FIG. 5C, the portions of the first auxiliary oxide layer 502 exposed through the patterned photoresist 504 are etched, so that a second auxiliary oxide layer 506 is left in each second trench 160. As shown in FIG. 5D, the patterned photoresist 504 is removed, and the remaining first auxiliary oxide layer 502 and the remaining second auxiliary oxide layer 506 are etched, so that the second auxiliary oxide layer 506 left in each second trench 160 disappears, and the first auxiliary oxide layer 502 is etched to leave an oxide layer disposed on the bottom wall of each first trench 140 to serve as the second oxide layer 1541. Therefore, the second oxide layer 1541 is disposed on the bottom wall of each first trench 140, and the thickness of the second oxide layer 1541 is greater than that of the first oxide layer 1521 as shown in FIG. 4F.

As shown in FIG. 5E, an oxide layer 508 is formed to cover the epitaxial layer 104, the first trenches 140, and the second trenches 160 by using the thermal oxidation manner. A polysilicon layer 510 is formed on the oxide layer 508 by using the thin-film deposition technique, and the polysilicon layer 510 fills the first trenches 140 and the second trenches 160. As shown in FIG. 5F, the polysilicon layer 510 is back etched to remove a portion of the oxide layer 508 and a portion of the polysilicon layer 510 which go beyond the first trenches 140 and the second trenches 160. The remaining oxide layer 508 disposed on the two side walls of each first trench 140 and the second oxide layer 1541 is the third oxide layer 1543 to serve as a gate oxide layer. The remaining polysilicon layer 510 disposed on the third oxide layer 1543 and filling each first trench 140 is the second gate electrode 1545. The second oxide layer 1541, the third oxide layer 1543, and the second gate electrode 1545 constitute the second gate structure 154. The remaining oxide layer 508 disposed on the bottom wall and the two side walls of each second trench 160 is the fourth oxide layer 1721 to serve as a gate oxide layer. The remaining polysilicon layer 510 disposed on the fourth oxide layer 1721 and filling each second trench 160 is the third gate electrode 1723. The fourth oxide layer 1721 and third gate electrode 1723 constitute the third gate structure 172. Next, portions of the epitaxial layer 104 near the top surface thereof are transformed into the blocks of the body region 120 by the ion implantation manner, and then portions of the body region 120 near the top surface thereof are transformed into the source regions 180 by the ion implantation manner.

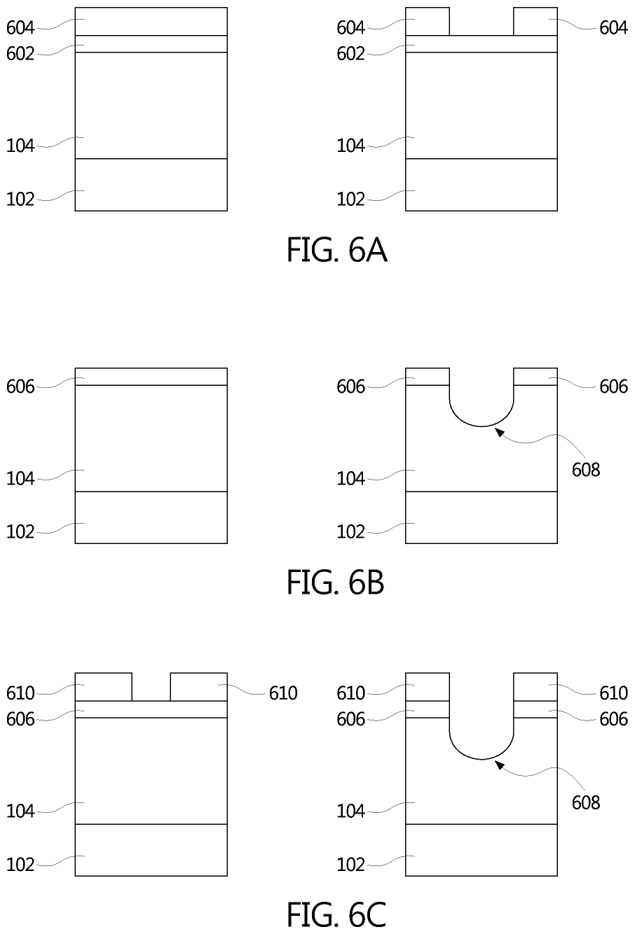

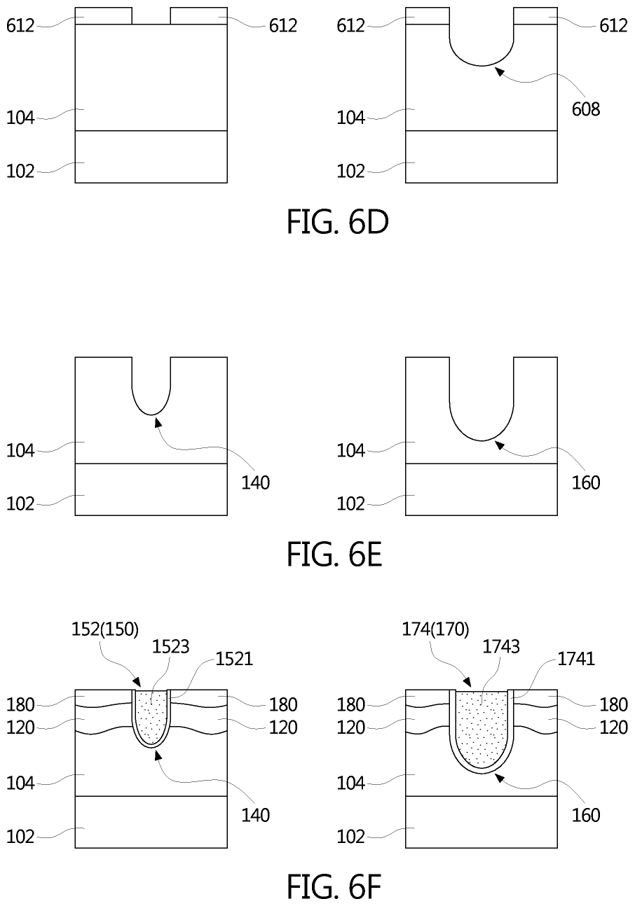

Please refer to FIG. 6A to FIG. 6E FIG. 6A to FIG. 6F are schematic flow diagrams of a method for fabricating the multi-trench MOSFET according to a third embodiment of the invention, which only show the schematic cross-sectional view taken along the line A-A in FIG. 1 (the left image in each drawing) and the schematic cross-sectional view taken along the line B-B in FIG. 1 (the right image in each drawing). In the third embodiment, each first trench 140 uses the first gate structure 152, and each second trench 160 uses the fourth gate structure 174. As shown in FIG. 6A, the substrate 102 is provided, and the epitaxial layer 104 is formed on the substrate 102. The substrate 102 and the epitaxial layer 104 constitute the drain region 100. A hard mask 602 is formed on the epitaxial layer 104, and a first patterned photoresist 604 is formed on the hard mask 602. The first patterned photoresist 604 exposes portions of the hard mask 602 corresponding to the second trenches 160. As shown in FIG. 6B, the portions of the hard mask 602 exposed through the first patterned photoresist 604 are etched to form a first patterned hard mask 606, and then the first patterned photoresist 604 is removed. The epitaxial layer 104 exposed through the first patterned hard mask 606 is etched to form auxiliary trenches 608. As shown in FIG. 6C, a second patterned photoresist 610 is formed on the first patterned hard mask 606. The second patterned photoresist 610 exposes portions of the first patterned hard mask 606 corresponding to the first trenches 140 and the second trenches 160.

As shown in FIG. 6D, the portions of the first patterned hard mask 606 exposed through the second patterned photoresist 610 are etched to form a second patterned hard mask 612, and then the second patterned photoresist 610 is removed. The second patterned hard mask 612 exposes portions of the epitaxial layer 104 corresponding to the first trenches 140 and the auxiliary trenches 608. As shown in FIG. 6E, the portions of the epitaxial layer 104 exposed through the second patterned hard mask 612 are etched to form the first trenches 140 and the second trenches 160. Each second trench 160 is obtained by further etching the corresponding auxiliary trench 608, so the depth of the second trench 160 is greater than that of the first trench 140. As shown in FIG. 6F, by the steps shown in FIG. 4D to FIG. 4F, the first oxide layer 1521 is formed on the bottom wall and the two side walls of the first trench 140 to serve as a gate oxide layer, and the first gate electrode 1523 is formed on the first oxide layer 1521 and fills the first trench 140. The first oxide layer 1521 and the first gate electrode 1523 constitute the first gate structure 152. The fifth oxide layer 1741 is form on the bottom wall and the two side walls of the second trench 160 to serve as a gate oxide layer, and the fourth gate electrode 1743 is formed on the fifth oxide layer 1741 and fills second trench 160. The fifth oxide layer 1741 and the fourth gate electrode 1743 constitute the fourth gate structure 174. Next, portions of the epitaxial layer 104 near the top surface thereof are transformed into the blocks of the body region 120 by the ion implantation manner, and then portions of the body region 120 near the top surface thereof are transformed into the source regions 180 by the ion implantation manner.

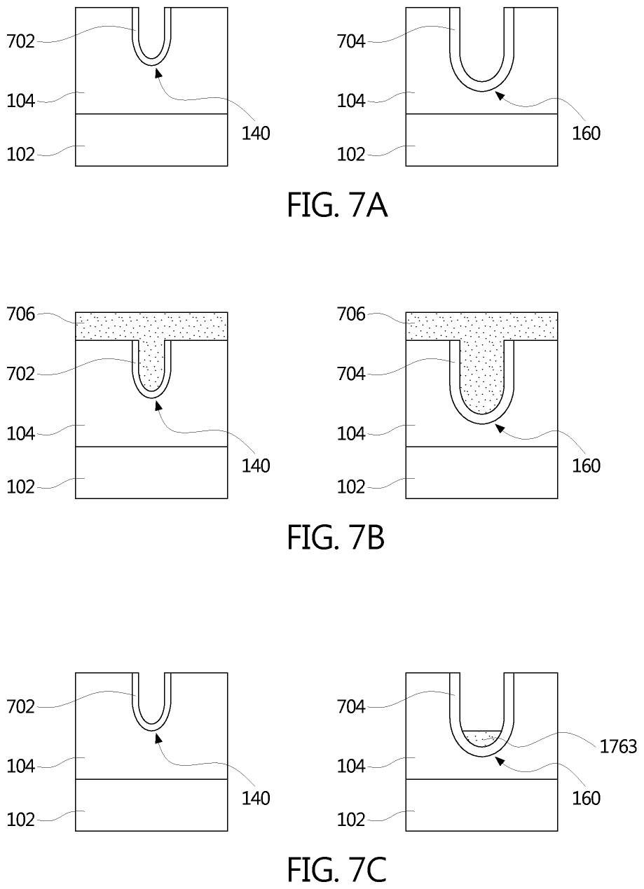

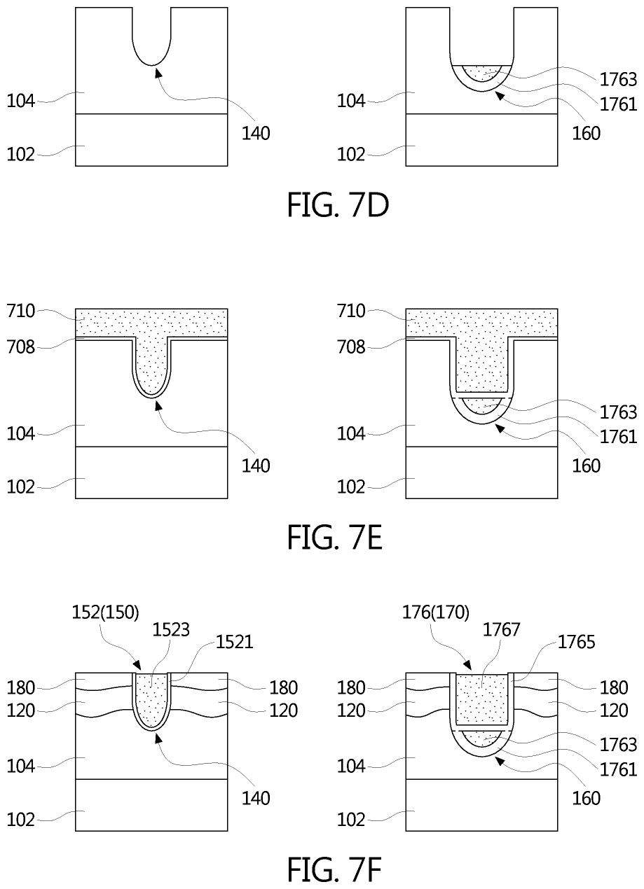

Please refer to FIG. 7A to FIG. 7F. FIG. 7A to FIG. 7F are schematic flow diagrams of a method for fabricating the multi-trench MOSFET according to a fourth embodiment of the invention, which only show the schematic cross-sectional view taken along the line A-A in FIG. 1 (the left image in each drawing) and the schematic cross-sectional view taken along the line B-B in FIG. 1 (the right image in each drawing). In the fourth embodiment, each first trench 140 uses the first gate structure 152, and each second trench 160 uses the fifth gate structure 176. As shown in FIG. 7A, by the steps shown in FIG. 6A to FIG. 6E, the first trenches 140 and the second trenches 160 are formed on the epitaxial layer 104, and the depth of the second trench 160 is greater than that of the first trench 140. A sacrificial oxide layer 702 is formed on the bottom wall and the two side walls of each first trench 140, while a sacrificial oxide layer 704 is formed on the bottom wall and the two side walls of each second trench 160, by using the thermal oxidation manner. As shown in FIG. 7B, a polysilicon layer 706 is formed on the epitaxial layer 104 and the sacrificial oxide layers 702 and 704 by using the thin-film deposition technique, and the polysilicon layer 706 fills the first trenches 140 and the second trenches 160. As shown in FIG. 7C, the polysilicon layer 706 is back etched to leave a polysilicon layer disposed on the bottom wall of each second trench 160 to serve as the first shield electrode 1763. As shown in FIG. 7D, the sacrificial oxide layers 702 and 704, so that the sacrificial oxide layer 702 left in each first trench 140 disappears, and the sacrificial oxide layer 704 left in each second trench 160 is etched to leave a sacrificial oxide layer disposed on the bottom wall thereof to serve as the sixth oxide layer 1761. Therefore, the sixth oxide layer 1761 is disposed on the bottom wall of the second trench 160, and the first shield electrode 1763 is disposed on the sixth oxide layer 1761.

As shown in FIG. 7E, an oxide layer 708 is formed to cover the epitaxial layer 104, the first trenches 140, and the second trenches 160 by using the thermal oxidation manner. A polysilicon layer 710 is formed on the oxide layer 708 by using the thin-film deposition technique, and the polysilicon layer 710 fills the first trenches 140 and the second trenches 160. As shown in FIG. 7F, the polysilicon layer 710 is back etched to remove a portion of the oxide layer 708 and a portion of the polysilicon layer 710 which go beyond the first trenches 140 and the second trenches 160. The remaining oxide layer 708 disposed on the bottom wall and the two side walls of each first trench 140 is the first oxide layer 1521 to serve as a gate oxide layer. The remaining polysilicon layer 710 disposed on the first oxide layer 1521 and filling each first trench 140 is the first gate electrode 1523. The first oxide layer 1521 and the first gate electrode 1523 constitute the first gate structure 152. The remaining oxide layer 708 disposed on the two side walls of each second trench 160, the sixth oxide layer 1761, and the first shield electrode 1763 is the seventh oxide layer 1765 to serve as a gate oxide layer. The seventh oxide layer 1765 and the sixth oxide layer 1761 surround the first shield electrode 1763. The remaining polysilicon layer 710 disposed on the seventh oxide layer 1765 and filling each second trench 160 is the fifth gate electrode 1767. The sixth oxide layer 1761, the first shield electrode 1763, the seventh oxide layer 1765, and the fifth gate electrode 1767 constitute the fifth gate structure 176. Next, portions of the epitaxial layer 104 near the top surface thereof are transformed into the blocks of the body region 120 by the ion implantation manner, and then portions of the body region 120 near the top surface thereof are transformed into the source regions 180 by the ion implantation manner.

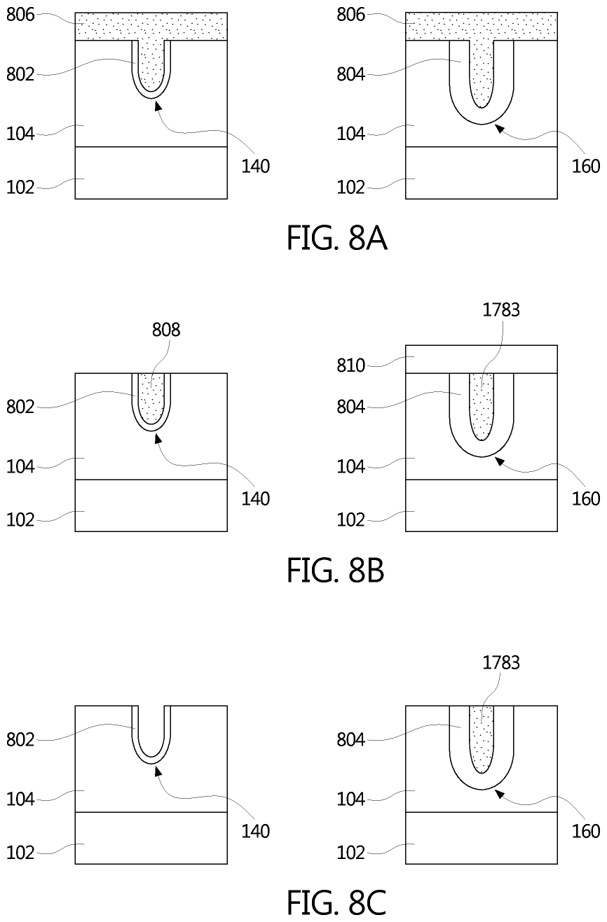

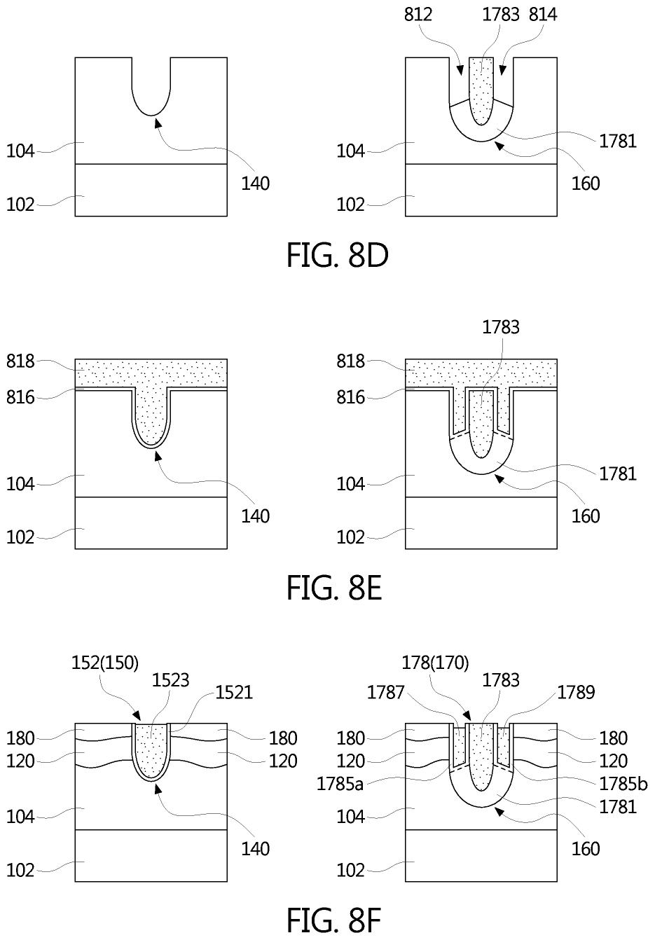

Please refer to FIG. 8A to FIG. 8F. FIG. 8A to FIG. 8F are schematic flow diagrams of a method for fabricating the multi-trench MOSFET according to a fifth embodiment of the invention, which only show the schematic cross-sectional view taken along the line A-A in FIG. 1 (the left image in each drawing) and the schematic cross-sectional view taken along the line B-B in FIG. 1 (the right image in each drawing). In the fifth embodiment, each first trench 140 uses the first gate structure 152, and each second trench 160 uses the sixth gate structure 178. As shown in FIG. 8A, by the steps shown in FIG. 7A and FIG. 7B, the first trenches 140 and the second trenches 160 are formed on the epitaxial layer 104, and the depth of the second trench 160 is greater than that of the first trench 140. A sacrificial oxide layer 802 is formed on the bottom wall and the two side walls of each first trench 140, while a sacrificial oxide layer 804 is formed on the bottom wall and the two side walls of each second trench 160, by using the thermal oxidation manner. A polysilicon layer 806 is formed on the epitaxial layer 104 and the sacrificial oxide layers 802 and 804 by using the thin-film deposition technique, and the polysilicon layer 806 fills the first trenches 140 and the second trenches 160. As shown in FIG. 8B, the polysilicon layer 806 is back etched to remove a portion of the polysilicon layer 806 which goes beyond the first trenches 140 and the second trenches 160. The remaining polysilicon layer 806 disposed in each first trench 140 is a polysilicon layer 808, and the remaining polysilicon layer 806 disposed in each second trench 160 is the second shield electrode 1783. Next, a patterned photoresist 810 is formed on the epitaxial layer 104, and the patterned photoresist 810 exposes the first trenches 140 but shields the second trenches 160. As shown in FIG. 8C, the polysilicon layer 808 in each first trench 140 exposed through the patterned photoresist 810 is etched to disappear, and then the patterned photoresist 810 is removed. As shown in FIG. 8D, the sacrificial oxide layers 802 and 804 are etched, so that the sacrificial oxide layer 802 in each first trench 140 disappears, and the sacrificial oxide layer 804 in each second trench 160 is etched to leave an oxide layer disposed on the bottom wall thereof to serve as the eighth oxide layer 1781. Therefore, the eighth oxide layer 1781 is disposed on the bottom wall of the second trench 160, the second shield electrode 1783 is disposed on the eighth oxide layer 1781, and the second shield electrode 1783 divides the space of the second trench 160 into two trenches 812 and 814.

As shown in FIG. 8E, an oxide layer 816 is formed to cover the epitaxial layer 104, the first trenches 140, and the second trenches 160 by using the thermal oxidation manner. A polysilicon layer 818 is formed on the oxide layer 816 by using the thin-film deposition technique, and the polysilicon layer 818 fills the first trenches 140 and the second trenches 160 (including the trenches 812 and 814). As shown in FIG. 8E the polysilicon layer 818 is back etched to remove a portion of the oxide layer 816 and a portion of the polysilicon layer 818 which go beyond the first trenches 140 and the second trenches 160. The remaining oxide layer 816 disposed on the bottom wall and the two side walls of each first trench 140 is the first oxide layer 1521 to serve as a gate oxide layer. The remaining polysilicon layer 818 disposed on the first oxide layer 1521 and filling each first trench 140 is the first gate electrode 1523. The first oxide layer 1521 and the first gate electrode 1523 constitute the first gate structure 152. The remaining oxide layer 816 disposed on the eighth oxide layer 1781, one of the two side walls of the second trench 160, and a side surface of the second shield electrode 1783 is the ninth oxide layer 1785a to serve as a gate oxide layer, while the remaining oxide layer 816 disposed on the eighth oxide layer 1781, the other one of the two side walls of the second trench 160, and another side surface of the second shield electrode 1783 is the tenth oxide layer 1785b to serve as a gate oxide layer. The remaining polysilicon layer 818 disposed on the ninth oxide layer 1785a and filling the second trench 160 (the trench 812) is the sixth gate electrode 1787, while the remaining polysilicon layer 818 disposed on the tenth oxide layer 1785b and filling the second trench 160 (the trench 814) is the seventh gate electrode 1789. The eighth oxide layer 1781, the second shield electrode 1783, the ninth oxide layer 1785a, the tenth oxide layer 1785b, the sixth gate electrode 1787, and the seventh gate electrode 1789 constitute the sixth gate structure 178. Next, portions of the epitaxial layer 104 near the top surface thereof are transformed into the blocks of the body region 120 by the ion implantation manner, and then portions of the body region 120 near the top surface thereof are transformed into the source regions 180 by the ion implantation manner.

In an embodiment, the material used by the first oxide layer 1521 to the tenth oxide layer 1785b can be silicon dioxide or other dielectric material. In an embodiment, the material used by the first gate electrode 1523 to the seventh gate electrode 1789, the first shield electrode 1763, and the second shield electrode 1783 is not limited to above-mentioned polysilicon, and can be doped polysilicon, metal, or amorphous silicon.

Although the invention has been described in terms of the preferred embodiments, it is not limited thereto. It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A multi-trench MOSFET, comprising:
a drain region having a first conductivity type;
a body region having a second conductivity type opposite to the first conductivity type, the body region disposed on the drain region;
a plurality of first trenches disposed side by side and extending in a first direction, the plurality of first trenches passing through the body region to enter into the drain region;
a plurality of first gates disposed in the plurality of first trenches respectively;
a plurality of second trenches disposed side by side and extending in a second direction different from the first direction, the plurality of second trenches passing through the body region to enter into the drain region, the plurality of first trenches and the plurality of second trenches being connected to divide the body region into a plurality of blocks, a width of each of the plurality of second trenches being 1.5 to 4 times that of each of the plurality of first trenches;
a plurality of second gates disposed in the plurality of second trenches respectively; and
a plurality of source regions having the first conductivity type, the plurality of source regions disposed in the body region and abutting the plurality of first trenches and the plurality of second trenches.

2. The multi-trench MOSFET of claim 1, wherein each of the plurality of first gates uses a first gate structure or a second gate structure;
wherein the first gate structure comprises:
a first oxide layer disposed on a bottom wall and two side walls of corresponding one of the plurality of first trenches; and
a first gate electrode disposed on the first oxide layer and filling the corresponding one of the plurality of first trenches;
wherein the second gate structure comprises:
a second oxide layer disposed on the bottom wall of the corresponding one of the plurality of first trenches, a thickness of the second oxide layer is greater than that of the first oxide layer;
a third oxide layer disposed on the two side walls of the corresponding one of the plurality of first trenches and the second oxide layer; and
a second gate electrode disposed on the third oxide layer and filling the corresponding one of the plurality of first trenches.

3. The multi-trench MOSFET of claim 2, wherein if a depth of each of the plurality of second trenches is the same as that of each of the plurality of first trenches, each of the plurality of second gates uses a third gate structure, wherein the third gate structure comprises:
a fourth oxide layer disposed on a bottom wall and two side walls of corresponding one of the plurality of second trenches; and
a third gate electrode disposed on the fourth oxide layer and filling the corresponding one of the plurality of second trenches.

4. The multi-trench MOSFET of claim 3, wherein if the depth of each of the plurality of second trenches is greater than that of each of the plurality of first trenches, each of the plurality of second gates uses a fourth gate structure, a fifth gate structure, or a sixth gate structure;
wherein the fourth gate structure comprises:
a fifth oxide layer disposed on the bottom wall and the two side walls of the corresponding one of the plurality of second trenches; and
a fourth gate electrode disposed on the fifth oxide layer and filling the corresponding one of the plurality of second trenches;
wherein the fifth gate structure comprises:
a sixth oxide layer disposed on the bottom wall of the corresponding one of the plurality of second trenches;
a first shield electrode disposed on the sixth oxide layer;
a seventh oxide layer disposed on the two side walls of the corresponding one of the plurality of second trenches, the sixth oxide layer, and the first shield electrode, the seventh oxide layer and the sixth oxide layer surrounding the first shield electrode; and
a fifth gate electrode disposed on the seventh oxide layer and filling the corresponding one of the plurality of second trenches;
wherein the sixth gate structure comprises:
an eighth oxide layer disposed on the bottom wall of the corresponding one of the plurality of second trenches;
a second shield electrode disposed on the eighth oxide layer;
a ninth oxide layer disposed on the eighth oxide layer, one of the two side walls of the corresponding one of the plurality of second trenches, and a side surface of the second shield electrode;
a tenth oxide layer disposed on the eighth oxide layer, the other one of the two side walls of the corresponding one of the plurality of second trenches, and another side surface of the second shield electrode;
a sixth gate electrode disposed on the ninth oxide layer; and
a seventh gate electrode disposed on the tenth oxide layer, the sixth gate electrode and the seventh gate electrode filling the corresponding one of the plurality of second trenches.

5. The multi-trench MOSFET of claim 1, wherein the drain region comprises:
a substrate having the first conductivity type; and
an epitaxial layer having the first conductivity type, the epitaxial layer disposed on the substrate, the body region disposed on the epitaxial layer.

6. A method for fabricating the multi-trench MOSFET of claim 4, comprising:
providing the drain region;
forming the plurality of first trenches and the plurality of second trenches on the drain region;
forming the plurality of first gates and the plurality of second gates in the plurality of first trenches and the plurality of second trenches respectively;
forming the body region in a top portion of the drain region; and
forming the plurality of source regions in the body region.

7. The method of claim 6, wherein if the depth of each of the plurality of second trenches is greater than that of each of the plurality of first trenches, forming the plurality of first trenches and the plurality of second trenches comprises:
forming a hard mask on the drain region, and forming a first patterned photoresist on the hard mask, the first patterned photoresist exposing portions of the hard mask corresponding to the plurality of second trenches;
etching the portions of the hard mask exposed through the first patterned photoresist to form a first patterned hard mask, and then removing the first patterned photoresist;
etching a portion of the drain region exposed through the first patterned hard mask to form a plurality of auxiliary trenches;
forming a second patterned photoresist on the first patterned hard mask, the second patterned photoresist exposing portions of the first patterned hard mask corresponding to the plurality of first trenches and the plurality of second trenches;
etching the portions of the first patterned hard mask exposed through the second patterned photoresist to form a second patterned hard mask, and then removing the second patterned photoresist, wherein the second patterned hard mask exposing portions of the drain region corresponding to the plurality of first trenches and the plurality of auxiliary trenches; and
etching the portions of the drain region exposed through the second patterned hard mask to form the plurality of first trenches and the plurality of second trenches, wherein each of the plurality of second trenches is obtained by further etching corresponding one of the plurality of auxiliary trenches.

8. The method of claim 6, wherein if each of the plurality of first gates uses the second gate structure, forming the plurality of first gates and the plurality of second gates in the plurality of first trenches and the plurality of second trenches respectively comprising:
forming a first auxiliary oxide layer on the drain region by using a thin-film deposition technique, the first auxiliary oxide layer filling the plurality of first trenches and the plurality of second trenches,
forming a patterned photoresist on the first auxiliary oxide layer, the patterned photoresist exposing portions of the first auxiliary oxide layer corresponding to the plurality of second trenches;
etching the portions of the first auxiliary oxide layer exposed through the patterned photoresist, so that a second auxiliary oxide layer being left in each of the plurality of second trenches; and
removing the patterned photoresist, and etching the remaining first auxiliary oxide layer and the remaining second auxiliary oxide layer, so that the second auxiliary oxide layer left in each of the plurality of second trenches disappears, and the first auxiliary oxide layer is etched to leave an oxide layer disposed on the bottom wall of each of the plurality of first trenches to serve as the second oxide layer of the second gate structure.

9. The method of claim 6, wherein providing the drain region comprises:
providing a substrate having the first conductivity type; and
forming an epitaxial layer having the first conductivity type on the substrate;
wherein the substrate and the epitaxial layer constitute the drain region, the plurality of first trenches and the plurality of second trenches are formed on the epitaxial layer, and the body region is formed in a top portion of the epitaxial layer.
